(19) United States
(12) Patent Application Publication
(10) Pub. No.: US 2016/0035954 A1
(43) Pub. Date: Feb. 4, 2016

(54) THERMOELECTRIC PERFORMANCE OF CALCIUM AND CALCIUM-CERIUM FILLED N-TYPE SKUTTERUDITES

(71) Applicant: GM GLOBAL TECHNOLOGY OPERATIONS LLC, DETROIT, MI (US)

(72) Inventors: James R. Salvador, Royal Oak, MI (US); Daniel Thompson, Royal Oak, MI (US); Chang Liu, Sunnyvale, CA (US)

(21) Appl. No.: 14/445,174

(22) Filed: Jul. 29, 2014

(51) Int. Cl. H01L 35/18; B22F 3/12; B22F 9/06

(52) U.S. Cl. CPC H01L 35/18; B22F 9/06; B22F 3/12

(57) ABSTRACT

A method is disclosed for inserting elemental calcium and cerium as low cost fillers in n-type Co₄Sb₁₂ type skutterudite compositions for use in thermoelectric applications. It is found that the inclusion of calcium oxide (and to a lesser extent, cerium oxide) in the Co₄Sb₁₂ skutterudite compositions, as the filled-crystalline compositions are being made, markedly reduces the thermoelectric properties of the intended calcium-filled crystalline product. A synthesis process, including careful control of melt spinning of a melt of calcium-containing, or calcium and cerium-containing, cobalt and antimony composition, leads to the formation of substantially oxide-free, calcium filled-precursor particles that can be compacted, sintered, and transformed into calcium-filled n-type skutterudite billets that have excellent thermoelectric properties.

This invention was made with U.S. Government support under Agreement No. DE-EE0000014 awarded by the U.S. Department of Energy. The U.S. Government may have certain rights in this invention.

### TECHNICAL FIELD

This disclosure pertains to the synthesis of relatively inexpensive calcium-filled n-type cobalt-antimony skutterudites and calcium and cerium-filled n-type cobalt-antimony skutterudites that provide thermoelectric properties that are comparable to the much more expensive barium and ytterbium-filled cobalt-antimony skutterudites. More specifically, this invention pertains to such a synthesis, utilizing melt spinning and spark plasma sintering (also known as pulsed electrical current sintering or PECS) to form high performance thermoelectric legs of CaₓCo₄Sb₁₂ and CaₓCe_{y}Co₄Sb₁₂ compositions.

### BACKGROUND OF THE INVENTION

Thermoelectric devices are formed of two different (but complementary) thermoelectric materials and can produce an electrical current when separated junctions are subjected to a suitable temperature differential or can produce separate hot and cold junctions when powered with an electrical current. The power generation thermoelectric devices exploit the Seebeck effect, a phenomenon in which a temperature gradient is applied across a body and, as a result, an open circuit voltage, co-linear to the temperature gradient, is established. The sign of the voltage with respect to the applied temperature gradient is dependent on the nature of the majority charge carriers. Where a temperature difference exists between ends of a thermoelectric element, heated electrons (or holes) flow towards the cooler end. Where a pair of dissimilar thermoelectric semiconductor elements, that is a pair consisting of an n-type and a p-type element, are suitably connected together to form an electrical circuit, a direct current (DC) flows in that circuit.

The efficiency of a thermoelectric (TE) material to convert heat to electricity is quantified using the TE dimensionless figure of merit, ZT, which is defined as ZT=(α²T)/(ρ·κ), where α is the Seebeck coefficient, ρ is the electrical resistivity, κ is the thermal conductivity consisting of both an electrical (κₑ) and lattice (κ_{L}) portion, T is the absolute temperature, and α²/ρ is the power factor. The Seebeck coefficient is a property intrinsic to a thermoelectric material and is related to the voltage developed in response to a temperature gradient. When measuring the properties of a thermoelectric material, the Seebeck coefficient is often provided in units of microvolts per Kelvin (μV/K), the resistivity in milliOhms-centimeter (mΩ-cm), and the thermal conductivity in Watts per Kelvin-meter (W/m-K). In view of the direct relationship between the Seebeck coefficient and electrical conductivity (electrical conductivity is equal to the inverse of the electrical resistivity) and the inverse relationship with thermal conductivity, it is seen that the better thermoelectric materials are those that conduct electricity well but conduct heat poorly. A challenge is that in any material the electrical, Seebeck coefficient, and thermal conductivity are typically closely interrelated.

Several families of crystalline thermoelectric material compounds have been discovered and developed. Among these compounds are the skutterudites which include the mineral CoPn₃ (Pn=P, As, Sb). The skutterudites possess large cages intrinsic to their crystal structure as the result of corner sharing CoPn₆ octahedra. A large variety of cations, including lanthanides, alkaline earths, and alkali metals can be introduced, or filled, into these cages to create Einstein-like vibrational modes that can act to scatter phonons and donate electrons to the CoSb₃ matrix, respectively reducing κ and ρ. Skutterudites have been of interest to the TE community since it was first proposed that placing atoms in their crystallographic voids (2a Wyckoff site in the cubic Im 3̅ space group) would substantially reduce their thermal conductivity by introducing phonon-scattering centers. Such skutterudites are seen to have potential for mid to high-temperature TE applications.

Of these skutterudite compositions, CoSb₃, is a candidate example which may be suitable for automotive applications if its thermoelectric performance can be enhanced at a suitable cost. Cubic CoSb₃ has a body centered cubic crystal structure with a void at the x=y=z=0 position. The crystal voids may be filled to some extent, for example, with rare-earth, alkaline-earth, or alkali metal elements. Such partial filling approaches may be used to adjust or tune thermoelectric properties of the crystalline material. The skutterudites display semiconductor properties and distinct compositions can be formed with p-type and n-type conductivity.

Double-filled YbₓBa_{y}Co₄Sb₁₂ with ZT values around 1.1 at 750 K offer good thermoelectric (TE) properties for use in automotive waste heat recovery and other applications. However, both the ytterbium and barium filler elements are expensive, and most rare earth elements are in limited supply. There is a need for a synthesis method that would enable the use of calcium, or of calcium and cerium (cerium is one of the more abundant and underutilized rare earth elements), as fillers in cobalt-antimony type skutterudites to yield TE properties comparable to those obtained in the more expensive YbₓBa_{y}Co₄Sb₁₂ compositions. So far, such a synthesis has not been accomplished.

### SUMMARY OF THE INVENTION

Methods and practices are provided that enable the synthesis of calcium-containing n-type Co₄Sb₁₂ compositions and calcium and cerium-containing n-type Co₄Sb₁₂ thermoelectric compositions. These methods and practices can yield such skutterudite compositions that have ZT values comparable to those of double-filled YbₓBa_{y}Co₄Sb₁₂.

In general, n-type skutterudite compositions of CaₓCo₄Sb₁₂ or of CaₓCe_{y}Co₄Sb₁₂ are prepared where 0.01<x<0.25 and where 0.02<y<0.15. While the effectiveness of the subject preparation method is demonstrated below in this specification using laboratory scale quantities of the materials, it is intended that the practice of the developed method will be most beneficial with much larger quantities, suitable for producing production quantities of the subject calcium-filled skutterudite thermoelectric materials in the kilogram weight range, or higher.

In general, it is suitable to start the synthesis process with a preformed, substantially oxygen-free solid composition of cobalt and antimony in skutterudite atomic proportions in a form for charging to a melting vessel. A predetermined proportion of particles or pieces of calcium or of a mixture of calcium and cerium are mixed with cobalt-antimony skutterudite composition in a suitable vessel under argon or other suitable non-oxidizing atmosphere. In some compositions it may be suitable to add cerium in the form of a cerium mischmetal. The vessel may, for example, be lined with boron nitride or other material that is non-reactive with these materials to be melted. Induction heating means is preferably used to heat and melt the mixture. The molten composition may be heated to a temperature of about 1200° C. to obtain a generally homogenous liquid of the metallic elements. Depending on the total mass of material to be melted, the preparation of the melt may be completed in a period of minutes.

The molten calcium-containing, or calcium and cerium-containing composition is now to be subjected to a melt spinning process to progressively form small ribbons or other rapidly solidified particle shapes that are substantially free of calcium oxide and any other metal oxides which are typically formed despite careful handling of the constituents in a non-oxidizing atmosphere or environment. It is found that the formation of calcium oxides are likely to be formed when the quantity of the melt reaches, for example, kilogram levels as is required in fabricating production quantities of thermoelectric billets or other TE element shapes. The melt may have been prepared in a suitable vessel for melt spinning. If not, it is transferred to such a vessel utilizing a non-oxidizing environment or practice.

Preferably, the liquid in the melt spinning vessel is maintained under an argon atmosphere (or the equivalent) with minimal oxygen content in a generally quiescent state so that any solid calcium oxides or cerium oxides can separate from the liquid and float to the top of the melt. This is to isolate such solid oxides from the liquid stream ejected from the vessel in forming the thermoelectric product. The pressure of the argon gas is increased to a suitable level, such as a few pounds per square inch of pressure, to eject a continuous stream of the molten composition, through a suitably sized or valve-controlled orifice at the bottom of the vessel, downwardly onto the circumference of a rotating quench wheel. When the liquid stream of predetermined flow rate hits the moving surface of the quench wheel, small fragments of solid particles (often ribbon-shaped) are continually formed in a fraction of a second and thrown from the wheel into a suitable recovery container. The quenching of the molten calcium-containing cobalt-antimony material is also preferably conducted in a chamber with a non-oxidizing atmosphere. The rate of rotation of the wheel is determined to provide the quenched ribbon particles with a crystalline microstructure, including a mixture of peritectic precursor phases such as Sb, CoSb, CoSb₂, as well as the desired Co₄Sb₁₂ cubic microstructure. It is considered important to minimize the formation of a calcium oxide phase. The rapid cooling and solidification of the melt is conducted to bind the elemental calcium and cerium as antimonides and also to encapsulate them in the microstructural matrix of the ribbon or like rapid solidification product. Further, it is found that the very rapid formation of the peritectic phases by a very rapid solidification process makes it possible to subsequently more quickly form the desired Co₄Sb₁₂ microstructure at a lower transformation temperature to further minimize the formation of calcium oxides.

The quench wheel may be formed, for example, of copper with a protective coating of chromium on the circumferential quench surface of the wheel. Where a substantial quantity of molten calcium-containing cobalt-antimony material is to be quenched, the wheel may be cooled, with water or other suitable coolant, so as to maintain a desired quench rate of the molten vertical stream of calcium-containing cobalt-antimony material that is striking the spinning quench wheel. The melt spin process is conducted so as to minimize any calcium oxide content in the particulate solid melt spun ribbon-like product. The minimization of the calcium oxide content may be accomplished, by careful attention to the management of the molten material as it is being depleted in the melt spinning process. Such practices may include, for example, (i) management of the atmosphere in which the melt is contained, (ii) management of the molten material within the vessel to permit separation of the lower density, solid calcium oxide at the upper surface of the melt, (iii) avoiding inclusion of floating calcium oxide in melt leading to the quenched material, and (iv) by examination of the quenched material and discarding calcium oxide-containing ribbon from the further processed material. Further, and as stated above, it is desirable to manage the cooling rate and process to encapsulate the calcium in the melt spun ribbon to resist and impede oxidation of the calcium (or calcium and cerium). It is preferred to form peritectic crystalline particles of precursor materials for the skutterudites in the melt spun product.

The particles of melt spun calcium-containing cobalt-antimony composition may be comminuted into generally uniform size particles for die compaction and sintering into shaped discs or the like for TE applications as n-type Ca-filled or n-type Ca and Ce-filled, cobalt-antimony bodies. The compacted particles may be consolidated into fully-densified TE elements for assembly into a TE module. The compacted particles may be heated from room temperature for example, to about 650° C., for example, over a period of minutes using a suitable heating and pressing process. For example, spark plasma sintering (also known as pulsed electrical current sintering or PECS) or a uniaxial hot pressing (HP) process may be used. Again the sintering process is conducted at a predetermined low temperature and relatively short pressing time to avoid the formation of calcium oxide while converting the precursor peritectic phases into calcium-filled or calcium and cerium-filled cubic crystals of n-type Co₄Sb₁₂. The managed application of melt spin processing can also thus obviate the need for long term annealing processes to achieve the desired crystal structure. We have found that such long term heating, even under managed atmospheres, promotes the formation of calcium oxide.

Thus, the carefully managed melt spinning of a calcium oxide-free skutterudite composition provides a useful method of forming relatively inexpensive n-type TE materials having exceptional ZT values, greater than about 1 at 750K.

The subject practices of introducing calcium, or calcium and cerium, into n-type skutterudite compositions of Co₄Sb₁₂ are applicable to n-type skutterudite compositions of Co₄Pn₁₂ where Pn=P, As, or Sb. And the methods of this invention for the introduction of calcium as a filler element are applicable to n-type compositions of Co₁₋ₓMₓ Pn where M is an element selected from the group consisting of nickel, manganese, and chromium and where x is greater than zero and less than or equal to one.

Other objects and advantages of our invention will be apparent from the detailed description of comparative examples, which follow in this specification.

### BRIEF DESCRIPTION OF THE DRAWINGS

FIG. 1 shows an operating representative thermoelectric module for producing electric power, comprising an assemblage of many p-type and n-type semiconductor elements electrically connected in series. The assemblage and its associated electrical conductors are positioned between two planar ceramic isolators, with one isolator exposed to a higher temperature than the other. Practices of this invention are useful in making highly effective n-type elements for such a thermoelectric module.

In the following graphs the designation MS+SPS or MS+HP indicates calcium-filled, cobalt-antimony skutterudite samples made using melt spinning and spark plasma sintering or melt spinning and a uniaxial hot pressing process, and the designation MQA indicates such samples made by a melting, quenching, and annealing process, as described in the text.

FIG. 2 is a graph of electrical resistivity (mΩ-cm) versus Temperature (K) for: MS+SPS samples Ca_{0.25}Co₄Sb₁₂ (dash-dot-dot line); Ca_{0.1}Ce_{0.1}Co₄Sb₁₂ (dash-dot line); Ca_{0.05}Ce_{0.15}Co₄Sb₁₂ (long dash line); Ca_{0.15}Ce_{0.075}Co₄Sb₁₂ (medium dash line); for the MS+HP sample Ca_{0.15}Ce_{0.075}Co₄Sb₁₂ (solid line), and for the MQA sample—Ca_{0.1}Ce_{0.1}Co₄Sb₁₂ (short dashed line). The inset shows the large difference between the same nominal composition samples prepared by MQA (short dashed line) and MS+SPS (dash-dot line).

FIG. 3 is a graph of the Seebeck coefficient, α, (μV/K), versus Temperature (K) for the MS+SPS samples Ca_{0.25}Co₄Sb₁₂ (dash-dot-dot line); Ca_{0.1}Ce_{0.1}Co₄Sb₁₂ (dash-dot line); Ca_{0.05}Ce_{0.15}Co₄Sb₁₂ (long dash line); Ca_{0.15}Ce_{0.075}Co₄Sb₁₂ (medium dash line); for the MS+HP sample Ca_{0.15}Ce_{0.075}Co₄Sb₁₂ (solid line); and for the MQA sample Ca_{0.1}Ce_{0.1}Co₄Sb₁₂ (short dashed line). The inset is a graph of the absolute value |α| of the Seebeck coefficient versus n, carrier concentration per cm³. The insert graph, with its negative slope, shows that these samples, represented by CaₓCe_{y}Co₄Sb₁₂ (horizontal dash) and Ca_{0.25}Co₄Sb₁₂ (circle), have a ˜n^{-1/3} dependence for α indicating that the rigid band approximation is reasonable for these materials and is consistent with other n-type filled skutterudites.

FIG. 4 is a graph of Power Factor (μW/cm-K²) versus Temperature (K) for MS+SPS samples Ca_{0.25}Co₄Sb₁₂ (dash-dot-dot line); Ca_{0.1}Ce_{0.1}Co₄Sb₁₂ (dash-dot line); Ca_{0.05}Ce_{0.15}Co₄Sb₁₂ (long dash line); Ca_{0.15}Ce_{0.075}Co₄Sb₁₂ (medium dash line); and for the MQA Ca_{0.1}Ce_{0.1}Co₄Sb₁₂ (short dash line).

FIG. 5 is a graph of both total (5a) and lattice (5b) thermal conductivities versus Temperature (K) for MS+SPS samples Ca_{0.25}Co₄Sb₁₂ (dash-dot-dot line); Ca_{0.1}Ce_{0.1}Co₄Sb₁₂ (dash-dot line); Ca_{0.05}Ce_{0.15}Co₄Sb₁₂ (long dash line); Ca_{0.15}Ce_{0.075}Co₄Sb₁₂ (medium dash line); for the MS+HP sample Ca_{0.15}Ce_{0.075}Co₄Sb₁₂ (solid line); and for the MQA sample Ca_{0.1}Ce_{0.1}Co₄Sb₁₂ (short dashed line) Lattice thermal conductivity was determined using the Wiedemann/Franz relationship with Lₒ=2.45E-8 V²/K².

FIG. 6 is a graph of the Dimensionless figure of merit (ZT) versus Temperature (K) for all samples: MS+SPS Ca_{0.25}Co₄Sb₁₂ (dash-dot-dot line); Ca_{0.1}Ce_{0.1}Co₄Sb₁₂ (dash-dot line); Ca_{0.05}Ce_{0.15}Co₄Sb₁₂ (long dash line); Ca_{0.15}Ce_{0.075}Co₄Sb₁₂ (medium dashed line); and for MQA Ca_{0.1}Ce_{0.1}Co₄Sb₁₂ (short dashed line).

### DESCRIPTION OF PREFERRED EMBODIMENTS

A purpose of this invention is to provide a method of forming n-type CaₓCo₄Sb₁₂ compositions and CaₓCe_{y}Co₄Sb₁₂ compositions with thermoelectric properties that make them suitable for use in thermoelectric devices for automotive applications which require that the compositions be formable into robust module structures that are adaptable to integration with vehicle power systems. As stated above, the processes of this invention are generally applicable to forming n-type skutterudite compositions of Co₄Pn₁₂ where Pn=P, As, or Sb. And the methods of this invention for the introduction of calcium as a filler element are applicable to n-type compositions of Co₁₋ₓMₓPn, where M is an element selected from the group consisting of nickel, manganese, and chromium and where x is greater than zero and less than or equal to one.

Before describing the subject synthesis methods it may be useful to describe the systems in which the n-type CaₓCe_{y}Co₄Sb₁₂ materials will be used.

Thermoelectric devices generate electricity by electrically connecting two thermoelectric elements of differing thermopower signs and exposing them to a temperature gradient. The capabilities of the device will depend both on the magnitude of the Seebeck coefficient of the thermoelectric elements, a material effect, and the magnitude of the temperature gradient. It is therefore desirable to have the absolute values of Seebeck coefficients be as large as possible.

Semiconductors are attractive candidate materials for thermoelectric elements because they may be doped with elements providing excess electrons or holes which results in large positive or negative values of the Seebeck coefficient of these materials predominately depending on the charge of the excess carriers.

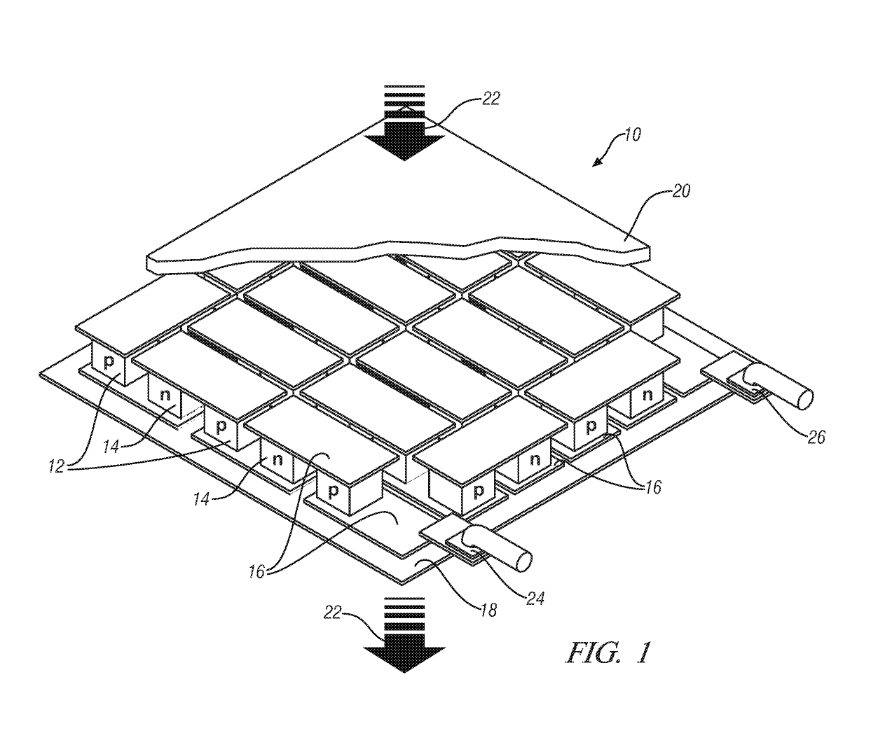

FIG. 1 shows a representative thermoelectric device 10, comprising a regular array of spaced-apart, alternating p-type 12 and n-type 14 thermoelectric elements connected to one another in series configuration by interconnected conductors 16 and attached to a plate at their top and bottom surfaces. Often both types of elements 12, 14 are the same size and shape. For example, they are square in cross-section for close-fitting and a few millimeters on a side. Their heights are uniform and of a few millimeters. In this illustration, seventeen p-type elements and seventeen n-type elements are alternately and progressively connected as p-type/n-type pairs in series DC connection from terminal 24 to terminal 26. In operation, the produced current flows from one terminal, up and down, through adjacent elements 12, 14 and conductors 16 to the other terminal.

In this representation it is intended that plate 20, the hot plate, is maintained at a higher temperature than plate 18, the cold plate. Obviously such a temperature gradient will produce a heat flow in the direction indicated by arrow 22. Electrical terminals 24 and 26 provide connection with an external load or with another thermoelectric device. In the configuration shown connector 26 will be at a more positive electrical potential that connector 24.

The subject methods are directed primarily to the preparation of n-type calcium and calcium cerium-filled cobalt-antimony skutterudites. We recognize that calcium and cerium are potentially readily available and low cost fillers for cobalt-antimony skutterudites, potentially to reduce thermal conductivity and improve electrical transport properties of the Co₄Sb₁₂ crystal structure. But previous efforts by others to use calcium as a filler, or calcium and cerium as fillers, have resulted in mediocre peak ZT values of about 0.45 at 800K.

The observation of poor TE performance in Ca-containing n-type skutterudites is not limited to single-filled samples; others found similarly poor performance in double-filled Yb—Ca and Ca—Ce skutterudites. Common to all of these reports is the requirement of large nominal compositions of Ca to approach the filling fraction limit (FFL) in the material, and yet the resistivities of these samples are still quite high particularly when compared to those of optimally doped n-type skutterudites with other filler species. We find that these high resistivities in the Ca-filled samples correlate to low Hall mobilities (μ_{H}), which is contrary to the general observation in n-type skutterudites that μ_{H} depends only on the carrier concentration and is virtually independent of the nature of the filler. Further, we observed that the band structure calculations performed on Ca-filled n-type skutterudites suggests that the presence of a large density of states that peak from the Ca 4_{S}-band located at the conduction band edge is the reason for their unusual electrical transport properties. Conversely, we contend that the low PH that has been reported in Ca-containing skutterudites to date is not intrinsic to Ca filling. Instead it is a result of secondary phases that are deleterious to TE performance, of which a likely candidate is calcium oxide.

We observed that such compositions were prepared by a process of producing a melt of the overall compositions, quenching the melt into ingots, reducing the solid ingots into a powder, forming the powder into TE disks or billets, and annealing the disks (or melting, quenching, and annealing, MQA). We concluded that, in the case of calcium-filled cobalt-antimony skutterudites, this MQA practice forms undesirable secondary calcium-containing phases. Herein it is shown that when a combination of carefully managed melt spinning (MS) followed by consolidation using spark plasma sintering (SPS or PECS), or other suitable sintering practice (such as uniaxial hot pressing (HP)), is applied to single or multi-filled Ca-containing skutterudites, large improvements in μ_{H} and ZT are realized by minimizing calcium oxide formation.

In the following description of laboratory scale experimental work, calcium oxide formation in melt spinning was anticipated and minimized by careful handling of the molten materials in a low oxygen-content environment and by leaving some residue in the container used in melt spinning. In larger volume production, the oxide content of the melt spun product may be minimized, for example, by retaining the upper, oxide-carrying portion of the molten metal in the melt spin vessel or by discarding the last portion of the melt spun product. In any practice, the melt spun material may be chemically analyzed for its content of calcium oxide or other unwanted oxide constituents. Further, the quench rate of the rapid solidification process may be managed to form desirable peritectic precursor phases in the solidified product (e.g., Sb, CoSb, and CoSb₂ along with some of the desired CoSb₃ skutterudite phase) that enable efficient transformation of the precursor phases into the calcium or calcium and cerium-filled skutterudite crystal structure under heating and pressing conditions that further minimize the formation of calcium oxides or other oxides in the TE product. The obviation of long term annealing by the use of this processing further reduces the likelihood of secondary oxide formation and further reduces processing costs.

Following is a description of the results of comparative practices of MQA and MS in the production of calcium-filled skutterudites.

### EXPERIMENTAL

### Sample Synthesis

Sample compositions will be denoted herein by their nominal compositions, and further compositional details are found in Table 1. Several MS+SPS CaₓCe_{y}Co₄Sb₁₂ samples were prepared by combining Co (arc melted pellets from Puratronic, 22 mesh powder, 99.995%) and Sb (Strem, bar, 99.999+%) in approximately a 1:3 ratio in a boron nitride crucible with subsequent induction melting at 1673 K for 30 s under an Ar atmosphere. The resulting melt was then combined with the appropriate amounts of Ca (Alfa Aesar, turnings, 99.9%), Ce (Alfa Aesar, rod, 99.8%), and Sb in a boron nitride crucible. The crucible and charge were sealed in a quartz tube under an Ar atmosphere, <3 ppm O₂ and <1 ppm H₂O, to prevent vapor loss and oxidation. A second induction melt step was performed at 1473 K for 5 minutes. These resulting ingots were then melt spun under Ar by induction heating them to 1473 K then ejecting them with a 2.5 psi pressure differential onto a rotating copper wheel with a tangential velocity of 20 m/s. Liquid potentially containing calcium oxide was retained in the liquid container from which the melt spin stream was ejected.

Ribbons were collected and ground in ambient air by hand for five minutes in an agate mortar and pestle. Consolidation was performed by SPS under a dynamic vacuum using a Dr. Sinter SPS-2040, which was pumped to ˜10 Pa and purged with Ar before the dynamic vacuum was allowed to reach ˜2 Pa. Approximately 6 g of powdered ribbons were loaded in a 12.7 mm internal diameter graphite die coated with boron nitride spray. A pressure of 50 MPa was applied and an on:off pulse ratio of 12:2 (32.4:5.4 ms) was selected. The sample was heated using a programmed temperature profile set to heat linearly from 25° C. to 650° C. over 10 minutes then held 650° C. for 20 minutes. At the end of the temperature profile the pressure was removed, and the sample was allowed to cool under vacuum. The resulting billets were approximately 12.7 mm diameter by 6 mm long cylinders. The densities (d) of the as-pressed samples were measured by mass and dimensions of the uncut billets. The relative density of all samples, as shown in Table 1, achieved at least 98% of the theoretical density, 7.64 g/cc for unfilled Co₄Sb₁₂.

TABLE 1

| Nominal | EPMA | Syn. | a | d | n × 10²⁰ | ρ | μ_{H} | α |
|---|---|---|---|---|---|---|---|---|
| composition | Composition | Tech. | (Å) | (%) | (cm⁻³) | (mΩ · cm) | (cm²/V · s) | (μV/K) |
| Ca_{0.4}Co₄Sb₁₂ | Ca_{0.2}Co₄Sb_{12.46} | MQA | 9.0498 | 92 | 2.8 | 2.60 | 7.2 | −114 |
| Ca_{0.2}Co₄Sb₁₂ | Ca_{0.13}Co_{4.0}Sb_{12.01} | MQA | | | 2.8 | 4.88 | 4.5 | −109 |
| Ca_{0.25}Co₄Sb₁₂ | Ca_{0.18}Co_{4.00}Sb_{12.48} | MS + SPS | 9.0391 | 98 | 3.6 | 0.43 | 40.3 | −118 |
| Ca_{0.1}Ce_{0.1}Co₄Sb₁₂ | Ca_{0.084}Ce_{0.065}Co_{4.00}Sb_{12.08} | MS + SPS | 9.0542 | 99 | 2.8 | 0.53 | 42.6 | −126 |
| Ca_{0.1}Ce_{0.1}Co₄Sb₁₂ | Ca_{0.039}Ce_{0.021}Co_{4.00}Sb_{12.05} | MQA | 9.0825 | 98 | 0.6 | 5.40 | 17.5 | −177 |
| Ca_{0.05}Ce_{0.15}Co₄Sb₁₂ | Ca_{0.059}Ce_{0.094}Co_{4.00}Sb_{12.16} | MS + SPS | 9.0520 | 98 | 3.3 | 0.52 | 36.3 | −120 |
| Ca_{0.15}Ce_{0.075}Co₄Sb₁₂ | Ca_{0.112}Ce_{0.054}Co_{4.00}Sb_{12.09} | MS + SPS | 9.0441 | 99 | 3.5 | 0.44 | 41.4 | −115 |

A sample with the nominal composition Ca_{0.1}Ce_{0.1}Co₄Sb₁₂ was prepared by a traditional MQA synthesis method to compare to its MS+SPS counterpart. For the MQA preparation the initial two-step induction process detailed for the MS+SPS processed samples described above was followed. The melt was then solidified by immersing its quartz container in water. The ingot was broken into chunks and flame sealed in a carbon coated quartz tube under a reduced atmosphere of 10⁻⁵ Torr and annealed at 973 K for 1 week. The annealed sample was then hand ground, cold pressed and annealed for an additional week at the same temperature.

Finally, a preliminary study was conducted on the effects of the sintering process employed on the electrical and thermal transport properties of the resulting billets. Another pressure sintering technique that was available was uniaxial hot pressing (HP). A similar heating rate and the same maximum sintering temperature of 650° C. were used, but a greater pressure of 160 MPa, and only a two minute hold time were used as the HP conditions. Billets consolidated by HP have the same dimensions and roughly the same density, 99% theoretical, as those from the SPS.

### Characterization Techniques

Phase identity and purity were assessed by powder x-ray diffraction (PXRD) on the billets using a D8-Advance DaVinci diffractometer with Cu K_{α}, radiation. Lattice parameters were determined by applying Rietveld refinement using Topas software. All reflections could be indexed to the skutterudite phase with no evidence of secondary phase for the Ca—Ce double-filled materials. The Ca single-filled material showed weak reflections corresponding to CoSb₂, which was also evident in the x-ray maps of Co. Electron probe microanalysis (EPMA) was performed to determine the element ratios of each sample. The EPMA derived compositions, as assessed by averaging the atomic ratios determined from eight randomly selected locations are shown in Table 1.

This averaging verifies that all the constituent elements were present in each grain, while indicating how homogeneously they are distributed within the sample. The standard deviations for Ca and Ce were significantly higher than the theoretical minimum, revealing that these atoms were not completely evenly distributed among the grains. The billets were cut into 3 bars and 1 disc for thermal and electrical transport measurements. Low temperature α, ρ, and κ (two probe) were measured from 5 K to 350 K using a Quantum Design physical property measurement system. Hall effect and four-probe ρ measurements were performed in a cryostat equipped with a 5 T magnet using a Linear Research AC resistance bridge. The carrier concentrations (n) were determined assuming transport from a single parabolic band and n=f|R_{H}·e, where f is the Hall factor taken as unity, R_{H} is the Hall coefficient, and e is the fundamental charge. The Hall mobilities were then computed with four-probe electrical resistivity values from the relation μH=1/ne ρ. High temperature α and ρ from 300 K to 773 K were measured with a Linseis LSR-3 system. High temperature κ from 300 K to 773 K was determined by κ=D×C_{P}×d, where thermal diffusivity (D) and heat capacity (C_{P}) were measured using an Anter FL 5000 and Netzsch DSC 404c, respectively. The κ_{L} was obtained by applying the Wiedemann-Franz relationship, κₑ=(Lₒ·T)/ρ, with the Lorenz number, Lₒ=2.45×10⁻⁸ WΩ/K², and κ_{L}=κ−κₑ. Verification of the high temperature properties for select samples was provided by Oak Ridge National Laboratory (ORNL) using a ULVAC ZEM-3 and Netzsch Laser Flash diffusivity measurement system.

### RESULTS AND DISCUSSION

### Sample Characterization

PXRD patterns of the double-filled MQA and the MS+SPS samples are qualitatively identical and represent phase pure skutterudites. Because rapid solidification occurs from a melt whose temperature was above the peritectic decomposition point, the XRD patterns of the melt spun ribbons revealed a mixture of Sb, CoSb, and CoSb₂ along with the desired CoSb₃ skutterudite phase. This result has been observed in other MS filled skutterudites, where the wheel speed (cooling rate) can play a role in both the evolution of the microstructure and the proportion of the various phases seen in the as-spun ribbons. The X-ray patterns of both the MQA sample and the MS+SPS sample shows that single-filled Ca and Ca—Ce double-filled samples prepared for this study obey Vegard's law as has been demonstrated in the literature for MQA Ca containing single-filled skutterudites. This indicates that despite the different preparation routes Ca and Ce are filling the crystallographic voids.

### Microstructural Analysis

Electron probe microanalysis results indicated that all the initial constituent elements (Ca, Ce, Co, and Sb) were present in each grain of the samples. A couple of key microstructural and compositional differences were noticeable between materials with the same nominal compositions prepared by either the MS+SPS or MQA routes as is shown for Ca_{0.1}Ce_{0.1}Co₄Sb₁₂ samples. First, the white regions in the Ca and Ce x-ray maps indicated high concentrations of these elements, which also correlated to elevated oxygen levels in the corresponding regions of the oxygen x-ray map. Thus, the grain boundary regions show higher levels of CaO and CeₓO_{y} in the MQA sample as compared to the MS+SPS sample. Second, the MS+SPS sample achieves a much higher filling fraction as compared to the MQA sample for the same starting nominal composition. Please refer to Table 1 for compositional details. Approximately twice the amount of Ca and three times the amount of Ce is incorporated in the skutterudite phase when the MS+SPS synthesis route is used. In previous reports on MQA Ca-filled skutterudites, large amounts of excess Ca, ˜0.40, were needed to approach the theoretical filling fraction limit of about 0.25. A measured filling fraction of ˜0.20 has been achieved using the MQA synthesis method. The formation of CaO during the synthesis was hypothesized by others to prevent the complete utilization of the Ca to fill the skutterudite voids because the ubiquitous oxide is sequestering potential fillers. The work here shows that the MS+SPS process more effectively incorporates Ca fillers into the voids than the MQA approach where MS+SPS Ca_{0.25}Co₄Sb₁₂ achieves comparable Ca filling to MQA Ca_{0.4}Co₄Sb₁₂. The reduced amounts of CaO and correspondingly higher Ca content in the MS+SPS skutterudite results in greater than a 100% improvement in ZT as compared to previously reported values.

### Electrical and Thermal Transport Properties

The R_{H} for all samples were negative over the entire temperature range investigated indicating electron dominated electrical transport consistent with the negative sign of α observed for all samples. The room temperature values of n and μ_{H} are listed in Table 1. The Ca and Ca—Ce filled MS+SPS samples have n that are akin to optimized Ba—Yb filled skutterudites, which also have ZT values in excess of unity at 773 K. The MQA Ca_{0.1}Ce_{0.1}Co₄Sb₁₂ sample had much lower n and μ_{H}. All the samples produced by MS+SPS show increasing n with increasing filling fraction consistent with previous findings. Above 100 K μ_{H} has a T^{-3/2} temperature dependence indicating that the main carrier scattering mechanism is from acoustical phonons. This is further supported by the n^{-1/3} carrier dependence of μ_{H}, which is also seen in traditionally prepared skutterudites with fillers such as, Laₓ, Baₓ, BaₓCe_{y}, and Ceₓ. Evident from the data presented in Table 1 for optimal carrier concentrations of about ˜3×10²⁰ cm⁻³ the μ_{H} of MQA Ca only filled samples in the literature are an order of magnitude lower than those presented here for MS+SPS samples. Hence, when Ca only filled skutterudites are prepared by MS+SPS with minimal amounts of secondary oxide they do in fact behave as one expects where μ_{H} of the n-type skutterudite depends solely on n and is independent of the filler atom's identity.

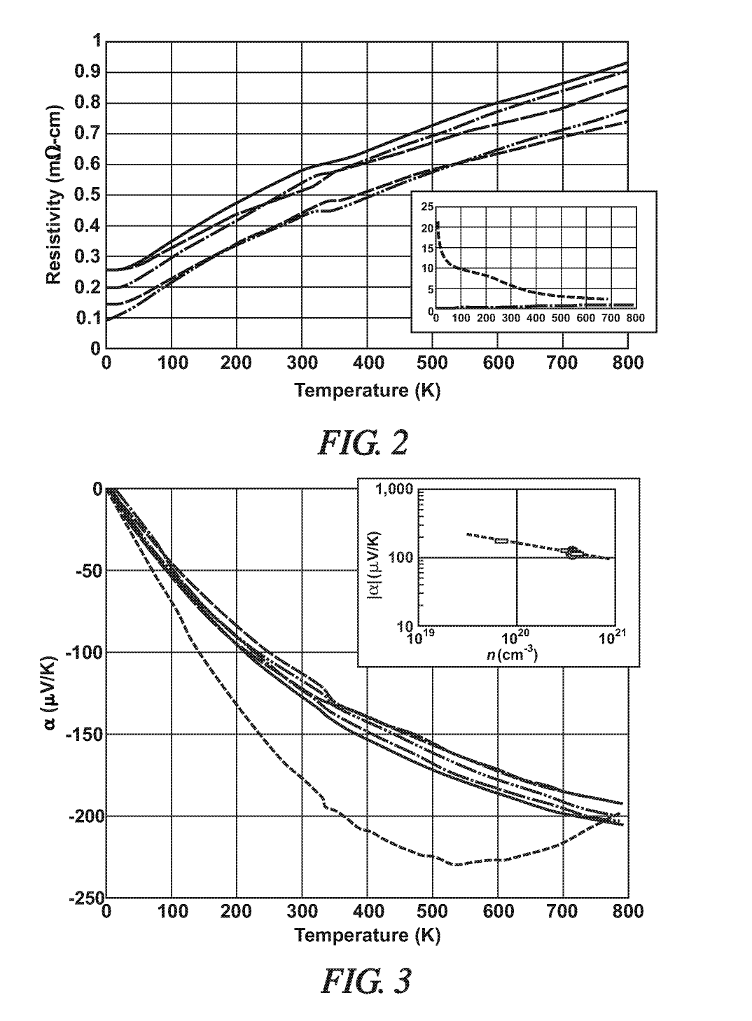

The temperature dependence of ρ from 4-800 K of all samples investigated is presented in FIG. 2. The inset of FIG. 2 shows the very large difference in the low temperature values and temperature dependence of ρ for Ca_{0.1}Ce_{0.1}Co₄Sb₁₂ prepared by MQA and MS-SPS. The significant result is that all the MS+SPS samples with either Ca only or Ca and Ce dual fillers show heavily doped degenerate semiconducting behavior in ρ that is typically observed in optimally doped filled skutterudites in contrast to previous reports. Shown in Table 1, skutterudite filling species being electropositive elements contribute a larger number of carriers as the filling concentration increases, and this is correlated to the decreasing ρ.

FIG. 3 shows the temperature dependence of α for all samples investigated. The approximately linear increase in α with temperature is also behavior typical for degenerate semiconductors and has been observed with similar magnitudes for highly filled MQA CaₓCo₄Sb₁₂ skutterudites. For the Ca_{0.1}Ce_{0.1}Co₄Sb₁₂ samples prepared by MQA and MS+SPS the difference in magnitude is a reflection of the filling fraction and carrier concentration. The α versus n values given in Table 1 possess a n^{-1/3} trend, as shown by the inset in FIG. 3. This concurs with others' findings that heavily doped Ca containing double-filled skutterudites feature n between 5×10¹⁹ and 5×10²⁰ cm⁻³ and agrees with the predicted behavior for the rigid band approximation.

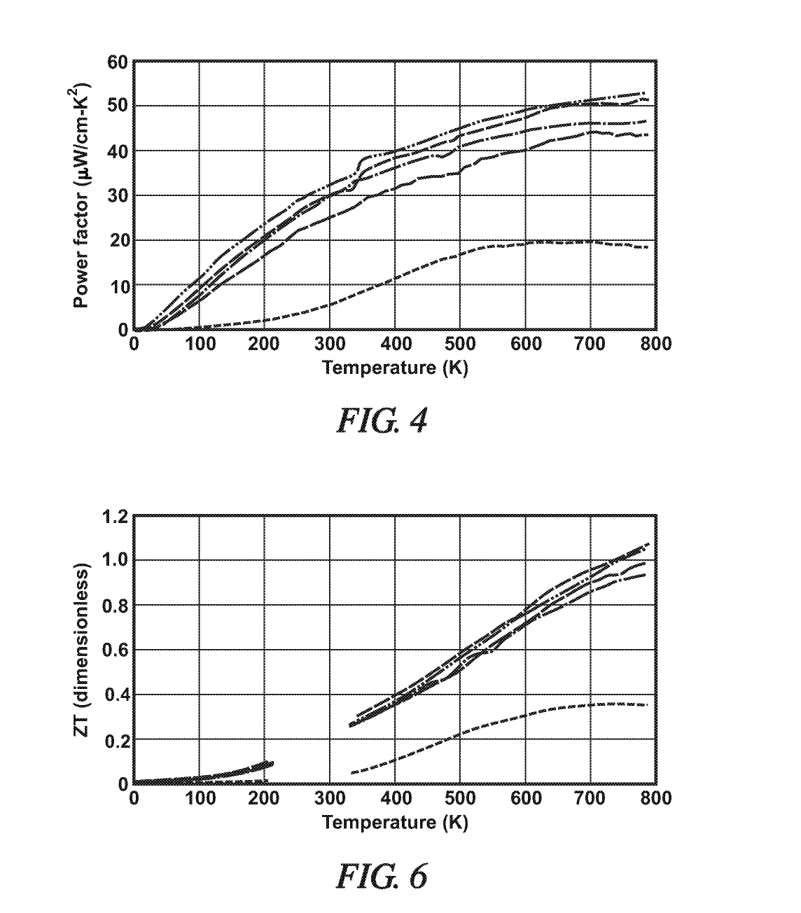

FIG. 4 shows the power factor of the MQA sample which agrees with previous reports, but when this composition is processed by MS+SPS it improves by over 100%. Also the MS+SPS sample single-filled with Ca (dash-dot-dot line) has a greater power factor (˜50 μW/cm-K² at 773 K) than previously reported for MQA materials determined to have similar EPMA compositions (˜20-30 μW/cm-K² at 773 K). These improvements in power factor along with those of the double-filled MS+SPS Ca—Ce samples are attributable to reduction in ρ, which is hypothesized to be the result of more careful processing, lower oxide content, and improved sample quality. Hence, the MS+SPS process benefits the electrical transport properties of samples that have some amount of Ca filler. But the negative effect of a secondary phase of oxide on electrical transport properties seems to be specific to CaO.

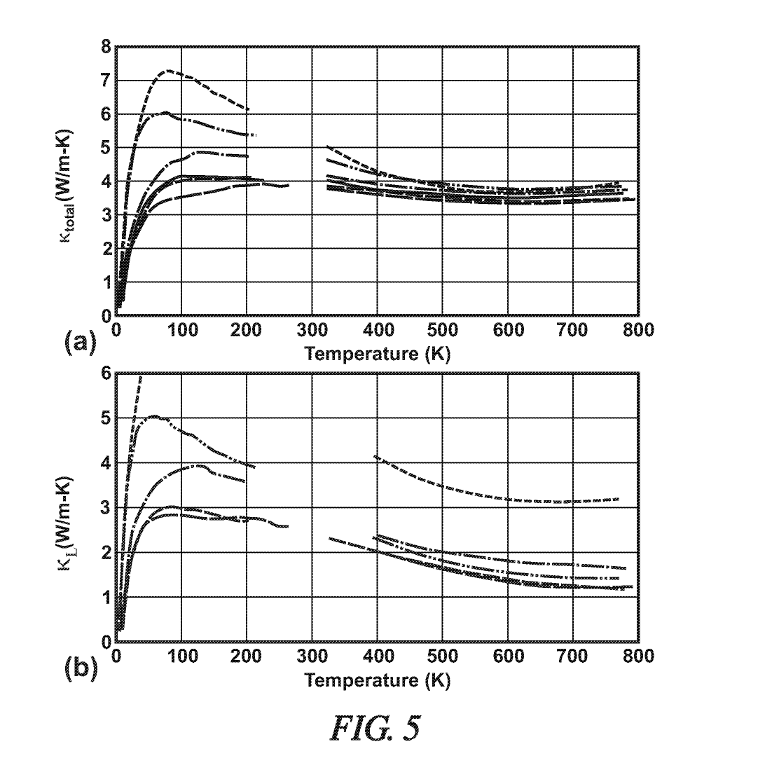

Averaging C_{P} data over temperatures ranging from 348-773 K gives values of 0.240 and 0.244 J/g·K for the Ca and Ca—Ce filled samples, respectively. Therefore, the measured C_{P} values used to calculate κ are reasonable considering the averaged Dulong-Petit value of these materials, 0.235 J/g·K. The total κ and the κ_{L} of all samples are shown in FIG. 5(a ) and (b), respectively. As expected, MS+SPS Ca—Ce filled materials show a trend of decreasing κ_{L} as filling fraction increases. Also at low temperatures a reduction in the peak κ_{L} is observable as first the MS+SPS samples transition from single-filled Ca (dash-dot-dot line) to double-filled Ca—Ce and then as the Ca—Ce samples have higher concentrations of fillers. One possible explanation for such behavior would be increased point defect scatting from the higher filling ratio and the heavier Ce filler species. The conjecture that the MS+SPS synthesis route is beneficial for the TE properties of Ca-filled skutterudites is bolstered by the result that the κ_{L} of the MS+SPS Ca-filled sample presented here (dash-dot-dot line) reaches a minimum value of κ_{L}˜1.4 W/m-K, whereas previous reports for similar compositions prepared by MQA have higher values of κ_{L}˜2.2 W/m-K. Comparing these κ_{L} values should be valid since the same Lₒ has been reported or assumed to be the same as those used in the literature for these materials. Hence, the MS+SPS synthesis route has reduced the Ca-filled skutterudites κ_{L} by 40% likely through an increased filler concentration. It is doubtful that nanograins of oxide are the contributing factor for this reduction as has been found in other skutterudites because the oxide grains are micron sized in the Ca-filled skutterudites, but the rather thermally conductive CaO, 30 W/m-K at 300K, could still contribute to lower κ_{L}. In summary, we have demonstrated that through careful control of synthesis conditions the oxidation of Ca fillers can be suppressed allowing it to be incorporated into the skutterudite where it reduces κ_{L} and behaves as an n-type dopant typical of other filler species.

As has now been shown in FIGS. 2, 3, and 5(a) the transport properties remained quite similar for the Ca_{0.15}Ce_{0.075}Co₄Sb₁₂ samples produced via MS+SPS (medium dashed line) or MS+HP (solid line). Also, as previously discussed, XRD shows both these samples to be phase pure. Hence it appears that typical solid state reactions and diffusion processes are occurring with either sintering mechanism, and the most significant improvements in transport properties, which are likely due to reduced amounts of secondary oxide phases, are arising from the MS portion of the MS+SPS process.

FIG. 6 shows the ZT curves of the samples. In order to construct the high temperature data set a polynomial fit was performed on the κ data. Then κ was calculated from the fit for the same temperatures at which ρ and α were measured enabling the determination of ZT above 300 K. In accord with all the transport data presented thus far, the Ca-filled skutterudite when prepared by MS+SPS shows an 80-100% improvement in ZT over previously published values. Likewise a 100% improvement was observed in double-filled Ca—Ce containing skutterudites as compared to previously published results. One should note that ZT values have a broad range of acceptable uncertainty, 15%, as discussed in the CRC reference handbook. The ZT values shown here for the best performing sample, MS+SPS Ca_{0.15}Ce_{0.075}Co₄Sb₁₂ (medium dashed line), are confidently stated. This is possible because upon observing the increased performance of this material due to the MS+SPS process, the inventors synthesized a second batch of MS ribbons of the same nominal composition to internally confirm these results, then external verification of high temperature (>300K) transport properties was performed at a separate lab, ORNL. The similar ZT performance of the Ca or Ca—Ce-filled MS+SPS skutterudites presented in this study is a strong indicator that Ca behaves as one usually envisages for the typical filler element, such as Yb, Ce, or Ba, in a skutterudite. This finding is contrary to previous reports by others.

A synthesis route, MS+SPS, has been described that leads to a twofold improvement in the thermoelectric performance of the lower cost formulations such as Ca or Ca—Ce filled n-type skutterudites, which can be an alternative to Yb—Ba filled skutterudites. MS+SPS samples displayed homogeneous microstructure with visibly less CaO and CeₓO_{y} appearing at the grain boundaries than observed in MQA samples. EPMA data also suggested that the MS+SPS synthesis technique had a more efficient filling rate for Ca than the MQA technique leading to more optimally doped materials with lower lattice thermal conductivity. In conclusion, Ca behaves similarly to other fillers, leading to heavily doped semiconductor trends in resistivity and Seebeck coefficient. We also find that reductions in the amount of Ca and Ce oxide lead to improved carrier mobilites, increased carrier concentration, and reduced lattice thermal conductivity as compared to previously published results. These results suggest that there are likely no band structure features that lead to unusual transport properties in MQA Ca-filled n-type skutterudites; instead, the irregularities can be ascribed to deleterious secondary phases.

As stated above in this specification, the particles of melt spun calcium-containing cobalt-antimony composition may be comminuted into generally uniform size particles for die compaction and sintering into shaped discs or the like for TE applications as n-type Ca-filled or n-type Ca and Ce-filled, cobalt-antimony bodies. The compacted particles may be consolidated into fully-densified TE elements for assembly into a TE module. The compacted particles may be heated from room temperature for example, to about 650° C., for example, over a period of minutes using a suitable heating and pressing process. For example, spark plasma sintering may be used or a uniaxial hot pressing process may be used. These pressing and sintering processes are conducted to obtain substantially fully densified compacts of fine grain particles in which the nominal grain size is in the range of about ten to fifty micrometers. The microstructure of the particles is characterized by a mosaic of such fine grains of calcium-filled or calcium and cerium-filled n-type skutterudites with substantially no inter-granular voids and no calcium oxide.

In spark plasma sintering equipment and processes a series of high frequency DC electrical pulses are applied through the compacted powder under vacuum while it is under mechanical pressure. This produces high localized temperatures between particles promoting solid-state diffusion at the particle surfaces and the desired consolidation of the particles. In accordance with practices of this invention a suitable on-off current frequency is selected and the particles are heated generally linearly from about room temperature (e.g., 25° C.) to about 650° C. over about ten minutes. The compacted material was held at about 650° C. for an additional 20 minutes. During this compaction and heating time the cobalt and antimony elements complete the formation of their cubic crystal structure and the filler elements, calcium or calcium and cerium cations diffuse into the crystals into their intended filler positions. The absence of calcium oxide permits the intended amount of calcium cations to enter the cubic crystal structure to provide the intended and desired thermoelectric properties. The elimination of the calcium oxide from the desired phase further improves carrier mobility and improves ZT.

While the SPS process is particularly suitable for consolidation of the melt spun particles into a desired TE member shape and the completion of the filled skutterudite synthesis, uniaxial hot pressing (HP) was also demonstrated above in this specification to be a suitable step in completion of the synthesis of calcium-filled skutterudites. A similar heating rate and hold time as compared to the SPS processing is used for hot pressing though a substantially higher pressure is required to obtain full density. Though not specifically investigated, it is likely that very short hold times at temperature can complete the preparation and consolidation process with the preservation of the state of art ZT levels. Thus, the limiting factor for cycle times in the hot press and SPS processes are the times required to obtain full densities and complete sintering.

Measurements performed on melt spun ribbons by differential scanning calorimetry indicate that pure phase skutterudites can be formed in less than one minute at temperatures in excess of 450° C. The onset temperature of transformation and the length of time required for the completion of the reaction are dependent on wheel speed, which dictates quench rate, such that higher wheel speeds (quench rates) lead to materials whose onset temperatures for conversion to pure phase skutterudites are lower and require less time for such conversion. Such fast transformations (which are helpful in maintaining low formation of calcium oxide) are not observed with melted and slow quenched or solidified materials when measured in a comparable manner.

Again the sintering process is conducted to avoid the formation of calcium oxide while converting the precursor phases into calcium-filled or calcium and cerium-filled cubic crystals of n-type Co₄Sb₁₂.

Practices of the invention have been illustrated by specific examples which are not intended as limitations of the scope of our invention.

1. A method of making n-type calcium filled Co₄Sb₁₂ skutterudite bodies, with a minimal content of calcium oxide, and having a predetermined ZT value of one or higher at a specified temperature, the method comprising;
forming a melt under a non-oxidizing atmosphere, the melt consisting of a composition of (i) calcium, cobalt, and antimony or of (ii) calcium, cerium, cobalt, and antimony, the melt being contained in a vessel with an opening at the bottom of the vessel, the melt having a volume with an upper surface that is contacted by the non-oxidizing atmosphere and a lower surface at the opening of the bottom of the vessel;
causing a flow of a stream of the melt from the vessel bottom opening downwardly onto a moving quench surface to progressively and continually quench the stream upon contact with the quench surface and to throw solidified particles of the composition from the wheel to a product retention area having a non-oxidizing atmosphere, the rate of solidification of the particles being determined to form a peritectic precursor phase in the solidified particles, and the rate of removal of the melt from the initial volume of the melt in the vessel being determined to permit the separation of solid calcium oxide material from the melt for retention at the upper surface of the melt;
removing the solidified particles from the product retention area and comminuting them into sized particles for compaction into thermoelectric elements;
compacting the sized particles in a die into a predetermined shape while progressively heating the particles to a temperature at which they are consolidated into non-porous thermoelectric elements of predetermined density, they are converted from the peritectic precursor phase into their filled skutterudite phase containing the calcium added to the melt, and they are substantially free of calcium oxide, such that the filled-skutterudite particles display a predetermined ZT value at a predetermined temperature.

2. A method of making n-type calcium-filled Co₄Sb₁₂ skutterudite bodies as recited in claim 1 in which a portion of the volume of melt composition carrying calcium oxide is retained in the vessel, separately from liquid that is quenched and solidified for compaction into a thermoelectric product.

3. A method of making n-type calcium filled Co₄Sb₁₂ skutterudite bodies as recited in claim 1 in which the rate of solidification yields particles containing crystalline peritectic phases, as detectable by x-ray diffraction, comprising at least one of Sb, CoSb, CoSb₂, and Co₄Sb₁₂.

4. A method of making n-type calcium filled Co₄Sb₁₂ skutterudite bodies as recited in claim 1 in which the rate of solidification yields particles containing crystalline peritectic phases, as detectable by x-ray diffraction, comprising at least one of Sb, CoSb, CoSb₂, and Co₄Sb₁₂, the particles being further characterized as having calcium entrained within or between the peritectic phases.

5. A method of making n-type calcium-filled Co₄Sb₁₂ skutterudite bodies as recited in claim 1 in which the solidified particles are collected in successive portions as the volume of liquid in the vessel is removed and solidified, and a selected portion is analyzed for the presence of calcium oxide to determine its suitability for compaction into a thermoelectric product.

6. A method of making n-type calcium-filled Co₄Sb₁₂ skutterudite bodies as recited in claim 1 in which the composition of the consolidated thermoelectric product is CaₓCo₄Sb₁₂ or of CaₓCe_{y}Co₄Sb₁₂ where 0.01<x<0.25 and where 0.02<y<0.15.

7. A method of making n-type calcium-filled Co₄Sb₁₂ skutterudite bodies as recited in claim 1 in which the composition of the consolidated thermoelectric product is CaₓCo₄Sb₁₂ or of CaₓCe_{y}Co₄Sb₁₂ where 0.01<x<0.25 and where 0.02<y<0.15, and where the product has a value of ZT that is greater than 1.0 at a temperature of 750K.

8. A method of making calcium-filled n-type Co₄₋ₓMₓPn₁₂ skutterudite bodies, where Pn is an element selected from the group consisting of phosphorus, arsenic, and antimony, M is an element selected from the group consisting of chromium, nickel, and manganese, and x has a value greater than zero and less than or equal to one; the calcium filled skutterudite having a minimal content of calcium oxide, and having a predetermined ZT value of one or higher at a specified temperature, the method comprising;
forming a melt under a non-oxidizing atmosphere, the melt comprising cobalt and a Pn element as skutterudite forming constituents with calcium or calcium and cerium as the only constituents in the melt that are intended as a filler for a skutterudite product, the melt being contained in a vessel with an opening at the bottom of the vessel, the melt having a volume with an upper surface that is contacted by the non-oxidizing atmosphere and a lower surface at the opening of the bottom of the vessel;
causing a flow of a stream of the melt from the vessel bottom opening downwardly onto a moving quench surface to progressively and continually quench the stream upon contact with the quench surface and to throw solidified particles of the composition from the wheel to a product retention area having a non-oxidizing atmosphere, the rate of removal of the melt from the initial volume of the melt in the vessel being determined to permit the separation of solid calcium oxide material from the melt for retention at the upper surface of the melt;
removing the solidified particles from the product retention area and comminuting them into sized particles for compaction into a thermoelectric element;
compacting the sized particles in a die into a predetermined shape while progressively heating the particles to a temperature at which they are consolidated into thermoelectric elements of predetermined density that are substantially free of calcium oxide such that the particles display a predetermined ZT value at a predetermined temperature.

9. A method of making n-type calcium-filled Co₄₋ₓMₓPn₁₂ skutterudite bodies as recited in claim 8 in which a portion of the volume of melt composition carrying calcium oxide is retained in the vessel, separately from liquid that is quenched and solidified for compaction into a thermoelectric product.

10. A method of making n-type calcium filled Co₄₋ₓMₓPn₁₂ skutterudite bodies as recited in claim 8 in which the rate of solidification yields particles containing crystalline peritectic phases, as detectable by x-ray diffraction, comprising at least one of Pn, CoPn, CoPn₂, and Co₄₋ₓMₓPn₁₂.

11. A method of making n-type calcium filled Co₄₋ₓMₓPn₁₂ skutterudite bodies as recited in claim 8 in which the rate of solidification yields particles containing crystalline peritectic phases, as detectable by x-ray diffraction, comprising at least one of Pn, CoPn, CoPn₂, and Co₄₋ₓMₓPn₁₂, the particles being further characterized as having calcium entrained within or between the peritectic phases.

12. A method of making n-type calcium-filled Co₄₋xMₓPn₁₂ skutterudite bodies as recited in claim 8 in which the solidified particles are collected in successive portions as the volume of liquid in the vessel is removed and solidified, and a selected portion is analyzed for the presence of calcium oxide to determine its suitability for compaction into a thermoelectric product.

13. A method of making n-type calcium-filled Co₄₋xMₓPn₁₂ skutterudite bodies as recited in claim 8 in which the composition of the consolidated thermoelectric product is CaₓCo₄xMₓPn₁₂ or of CaₓCe_{y}Co₄₋xMₓPn₁₂ where 0.01<x<0.25 and where 0.02<y<0.15.

14. A method of making n-type calcium-filled Co₄₋xMₓPn₁₂ skutterudite bodies as recited in claim 8 in which the composition of the consolidated thermoelectric product is CaₓCo₄₋xMₓPn₁₂ or of CaₓCe_{y}Co₄₋ₓMₓPn₁₂ where 0.01<x<0.25 and where 0.02<y<0.15, and where the product has a value of ZT that is greater than 1.0 at a temperature of 750K.

15. A method of making n-type calcium-filled Co₄Sb₁₂ skutterudite bodies as recited in claim 1 in which the thermoelectric elements are characterized by grains having sizes in the range of ten to fifty micrometers and the density of the thermoelectric elements is at least 97% of the theoretical density of the composition.

16. A method of making n-type calcium-filled Co₄₋xMₓPn₁₂ skutterudite bodies as recited in claim 8 in which the thermoelectric elements are characterized by grains having sizes in the range of ten to fifty micrometers and the density of the thermoelectric elements is at least 97% of the theoretical density of the composition.
